(19) United States
(12) Patent Application Publication
(10) Pub. No.: US 2012/0132259 A1
(43) Pub. Date: May 31, 2012

(54) COLLECTOR MODULE FOR A SOLAR THERMAL SYSTEM

(76) Inventor: Brian Wilkinson, Kirkland (CA)

(21) Appl. No.: 13/384,188

(22) PCT Filed: Jul. 6, 2010
(86) PCT No.: PCT/CA2010/001051

§ 371 Date: Jan. 13, 2012

Related U.S. Application Data
(60) Provisional application No. 61/223,199, filed on Jul. 6, 2009.

(51) Int. Cl. H01L 31/058; F24J 2/24

(52) U.S. Cl. 136/248; 126/663

(57) ABSTRACT

A solar thermal system for transporting air is provided. The solar thermal system comprises a backpass collector having collector modules which transport air in parallel. Each collector module includes an intake channel, an air intake, a return channel, a connector connecting the intake channel to the return channel, and an absorber surface for absorbing energy. The solar thermal system also comprises a plenum for receiving air in parallel from each return channel. The plenum has a receiving face which includes a plurality of alternating openings and closures, where each opening is aligned with a respective return channel and each closure is aligned with a respective intake channel. For each collector module, the outside air is drawn into the intake channel, is conveyed out of the intake channel and into the return channel by the connector, and passes from the return channel into the plenum.

### RELATED APPLICATIONS

This application is the U.S. National Phase under 35 U.S.C. §371 of International Application No. PCT/CA2010/001051, filed on Jul. 6, 2010, which in turn claims the benefit of U.S. Provisional Application No. 61/223,199, filed on Jul. 6, 2009, the disclosures of which Applications are incorporated by reference herein.

### FIELD OF THE INVENTION

The present invention relates to solar thermal systems and the like. More particularly, and in its preferred embodiment, the present invention relates to a collector module for a thermal heating system.

### BACKGROUND OF THE INVENTION

Solar thermal systems are known in the art. Such systems are typically mounted to the exterior of a building, either covering the walls or the roof, and can be used to heat either fresh air that is brought into the building, or recirculated air from inside the building for the ventilation system. Heat energy enters the system via a collector and is transported by a ventilation duct. Typically, the heated air travels to a plenum, which is kept at a lower pressure than atmospheric, and into the ventilation system. Conventional active solar air conditioning systems for heating or cooling using a collector typically fall into one of two categories—glazed or unglazed systems.

Glazed collectors are typically closed loop systems wherein the air to be heated is enclosed within the space it is heating and this same air is recycled through the collector. Glazed collectors are typically designed for space heating and cooling applications and are comprised of an exterior glazing and an internal absorber plate. The absorber plate is provided in direct contact with a heat transfer fluid and the whole system is contained within a single assembly usually no more than 3.0 m² in size. Such collectors are generally designed only for residential or light commercial applications due to the limited amount of total air volume they can accommodate.

Unglazed systems are typically categorized as either transpired or backpass collectors. Transpired collectors generally consist of a dark exterior absorber with small holes spaced uniformly across its surface. As sunlight strikes the dark surface, the collector absorbs the heat and conducts it from the surface. A thermal boundary layer of air is formed on the exterior of the absorber. This heated layer is pulled into the holes distributed over the absorber before the heat can escape by the forces of wind on the exterior of the absorber.

In a backpass system, sunlight heats a dark surface and incoming air is heated as it is passed behind the non-perforated absorber. While inexpensive and simple to construct, backpass systems typically require that the air must travel across the back of the absorber for a considerable distance, preferably in a turbulent flow, so as to improve the convective heat transfer on the back side of the absorber.

It is known that backpass collectors in which the air must travel only a short distance will have lower solar efficiency. Furthermore, it has been demonstrated that the larger the amount of air to be heated, the greater the depth of the cavity must be, in which the air will circulate. This increase in depth typically minimizes the percentage of air that comes in contact with the inner side of the absorber, thereby lowering the solar efficiency of the collector. Previous attempts to increase air flow and reduce the cavity depth have typically increased the fan power needed to operate the system.

Another drawback with existing backpass collectors relates to the location of their air intake. Well-known industry standards, such as the ASHRAE standard 62.1-2007, specify the minimum distances that must be respected between the air intake and elements such as garage entries, truck loading areas or docks, driveways, parking spots, etc. Conventional backpass collectors have the air intake located at the bottom of the collectors, preventing them from receiving the hot air that rises along the outside of the collector. Further, having the air intake at the bottom of the collectors often makes it difficult to respect the aforementioned minimum distances required by industry standards. Placing the air intake at the bottom of the collectors is often impractical because of snow accumulation thereby restricting the air intake.

In light of the information above, it would be desirable to have a backpass collector that would overcome some of the aforementioned problems with the prior art.

### SUMMARY OF THE INVENTION

An object of the present invention is to provide a solar thermal system that satisfies at least one of the above-mentioned needs and is thus an improvement over other related devices.

Indeed, according to an aspect of the present invention, there is provided a solar thermal system for transporting air, the solar thermal system comprising:
a) a backpass collector comprising a plurality of collector modules for transporting air in parallel, each collector module comprising:
   i. an intake channel comprising opposite first and second ends;
   ii. an air intake formed at the first end of the intake channel;
   iii. a return channel extending alongside the intake channel and comprising opposite first and second ends, the first end of the return channel being proximate the second end of the intake channel;
   iv. a connector unit connecting the second end of the intake channel to the first end of the return channel;
   v. an absorber surface formed by the intake and return channels for absorbing energy;
b) a plenum for receiving air in parallel form the second end of each return channel, the plenum comprising a receiving face which includes a plurality of alternating openings and closures, each opening being aligned with a respective return channel and each closure being aligned with a respective intake channel; and wherein, for each of said collector modules, outside air is drawn into the intake channel via the air intake, is conveyed out of the intake channel and into the return channel by the connector, and passes from the return channel into the plenum.

According to another aspect of the present invention, there is provided a backpass collector including a plurality of the above-mentioned collector modules.

According to yet another aspect of the present invention, there is provided a solar heating system including the above-mentioned backpass collector and a plenum connected to each of the return channels.

The collector module(s) are preferably arranged vertically, but may also be arranged horizontally or at an orientation therebetween. The plenum preferably extends perpendicularly across the collector module(s).

Preferably, each collector module is made a metallic or non-metallic sheet or plate bent so as to interconnect with one another, the channels having a C-shaped cross section opening towards the wall of the building, with both channels aligned horizontally at the bottom of the wall, where they connect to the connector.

Advantageously, a collector module in accordance with the present invention can increase the length of the air path and the speed of the air circulating within the channels. In operation, a backpass collector including a plurality of side-by-side collector modules can draw in outside air through the air intakes located at the top of the collector module. The air then travels along the intake channel of the module and is then redirected by the connector and doubles back along the return channel. The absorber surface is heated by incident light and solar energy, and this energy is then transmitted to the air travelling through the channels. Finally, this heated air is conveyed to the plenum and directed towards the building's ventilation system.

### BRIEF DESCRIPTION OF THE DRAWINGS

The invention will be better understood upon reading the following non-restrictive description of the preferred embodiment thereof, made with reference to the accompanying drawings.

FIG. 1 is a perspective view of a solar thermal system in accordance with a preferred embodiment of the present invention without the hood shown.

FIG. 2 is a front view of a collector module of the system of FIG. 1 without the hood shown.

FIG. 3 is a front side perspective view of the top portion of a collector module, according to a preferred embodiment of the invention without the hood shown.

FIG. 4 is a back side perspective view of the top portion of the collector module of FIG. 3.

FIG. 5 is a back side perspective view of the bottom portion of the collector module of FIG. 3, with the connector not shown. FIG. 5A is a bottom view of the collector module of FIG. 5.

FIG. 6 is a vertical section of the collector through the short channel showing the plenum and hood.

FIG. 7 is a vertical section of the collector through the long channel showing the plenum and hood.

While the invention will be described in conjunction with examples of, it will be understood that it is not intended to limit the scope of the invention to such embodiments. On the contrary, it is intended to cover all alternatives, modifications and equivalents as may be included as defined by the appended claims.

### DETAILED DESCRIPTION OF PREFERRED EMBODIMENT OF THE INVENTION

In the following description, the same numerical references refer to similar elements. The embodiment shown in the figures is preferred, for exemplification purposes only.

Although the preferred embodiment of the present invention as illustrated in the accompanying drawings comprise various different components, and related components and corresponding parts of the present invention as shown consist of certain geometrical configurations as explained and illustrated herein, not all of these components and geometries are essential to the invention and thus should not be taken in their restrictive sense, i.e. should not be used to limit the scope of the present invention. It is to be understood, as also apparent to a person skilled in the art, that other suitable components and interactions there between, as well as other suitable geometrical configurations, may be used for the apparatus of the present invention, as will be briefly explained herein and as can be easily inferred here from by a person skilled in the art, without departing from the scope of the invention.

It will be appreciated that positional descriptions such as “upper”, “lower”, “top”, “bottom” and the like should, unless otherwise indicated, be taken in the context of the figures and should not be considered limiting. In relation to the embodiment of the present invention illustrated in the figures, the use of the term “top” refers to the end of the collector module closest to the plenum, and “bottom” refers to the end of the module closest to the connector. In addition, while the embodiment presented in the figures is oriented vertically, the collector module of the present application may be oriented differently, such as horizontally.

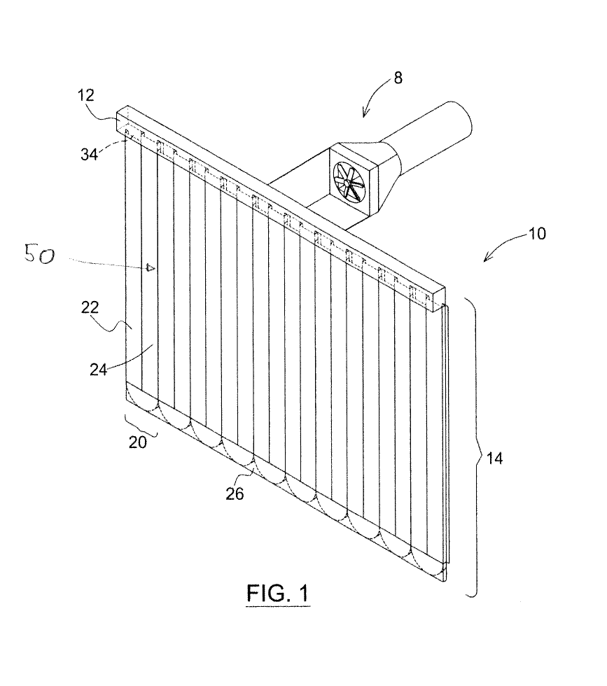

With reference to FIG. 1, a solar thermal system 10 according to a preferred embodiment of the invention is shown. The system 10 provides heated air to a building ventilation system 8 and comprises a plenum 12 which is supplied with heated air by a backpass collector 14. The solar thermal system 10 is fixable to a building's roof or façade, preferably facing south for buildings located in the northern hemisphere or north for buildings located in the southern hemisphere.

The plenum 12 extends over the wall surface, near the top edge of the building. The plenum 12 is preferably formed from a metallic or non-metallic sheet or plate, and is shaped as an elongated rectangular box, opening at its rear on the building wall and at its receiving side of the backpass collector 14. The plenum 12 can be affixed to the building wall structure with any convenient means, such as screws and bolts for example. The header 12 is sized according to the total air flow required, for maintaining a uniform pressure across the backpass collector 14 regardless of size or total air flow.

The backpass collector 14 comprises a plurality of collector modules 20. These modules are aligned side-by-side across the wall.

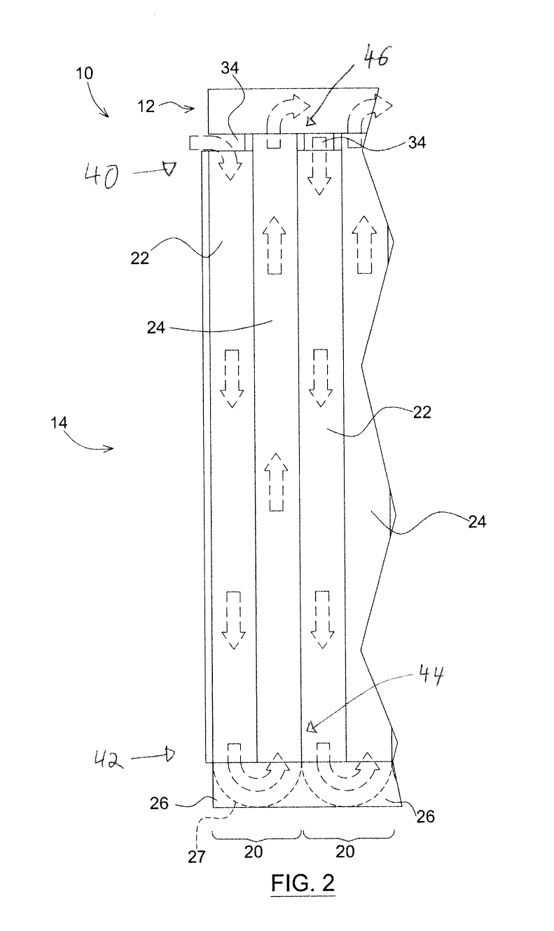

With additional reference to FIG. 2, each collector module 20 comprises an intake channel 22 and a return channel 24. These channels 22 and 24 extend alongside each other, preferably directly adjacent and parallel to one another, and each comprises a first end 40 and 42, and a second end 44 and 46, respectively.

In the illustrated embodiment, the intake channel 22 of each module 20 is shorter than the return channel 24. This difference in length creates a gap which forms an air intake at the top of the intake channel 22. As such, the intake and return channels 22 and 24 will hereinafter be referred to as the short channel 22 and the long channel 24. In addition, the collector modules 20 are oriented vertically and the first end 40 of each short channel 22 and the second end 46 of each long channel 24 will hereinafter be referred to as top ends. Similarly, the second end 42 of the short channel 22 and the first end 44 of the long channel 24 will hereinafter be referred to as bottom ends.

The channels 22 and 24 of each collector module 20 are closed at their bottom ends 42 and 44 by a connector unit 27. These connector units 27 are grouped in a larger connector 26 which extends across all the collector modules 20. The connector units 27 form partitions within the larger connector 26. Each connector unit 27 connects the short channel 22 with the long channel 24, routing the path of the air flowing therethrough back in the opposite direction, thus creating a serpentine passage for air. Such a path can be referred to as boustrophedonic.

In this preferred embodiment, both the short 22 and the long 24 channels are provided with the same shape, the only difference between the short one and the long one being their length. The channels 22 and 24 are both formed by a rectangular plate or sheet 28, preferably dark, which can be made of metallic or non-metallic material.

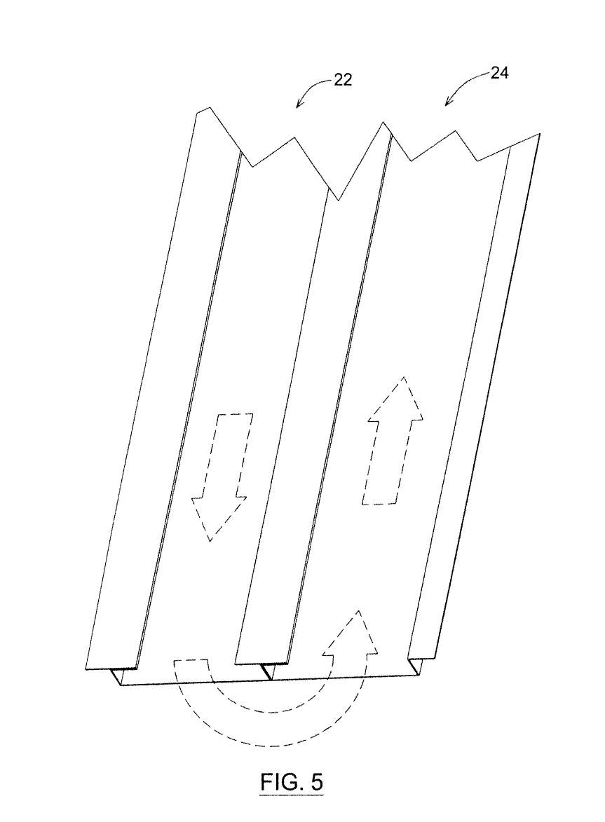

With reference to FIGS. 5 and 5A, the channels 22 and 24 preferably have C-shaped cross-sections opening towards the wall of the building. Each channel plate 28 is bent so as to form a female interconnection 30 along a first longitudinal side and a male interconnection 32 along the other longitudinal side. The female interconnection 30 preferably has an inverted C-shape cross-section while the male interconnection 32 is shaped as a flange. A given female interconnection 30 of a short channel 22 is fitted with the male interconnections 32 of a given long channel 24, and vice-versa such that short channels 22 of the assembled backpass collector 14 is interconnected and adjacent to a long channel 24. Preferably, screws are screwed along the longitudinal sides of interconnected channels 22 and 24 so as to provide a more secure connection. Of course, other means of connecting the short and long channels 22 and 24 can be considered.

Referring back to FIG. 2, the short 22 and long 24 channels of a collector module 20 are aligned at their bottom ends 42 and 22, while the short channel 22 is shorter than the long channel 24 at the top, thus creating an air intake opening 34 at the top end 40 of the module 20. It will be appreciated however that neither the top ends 40 and 46, nor the bottom ends 42 and 44 need be located adjacent one another.

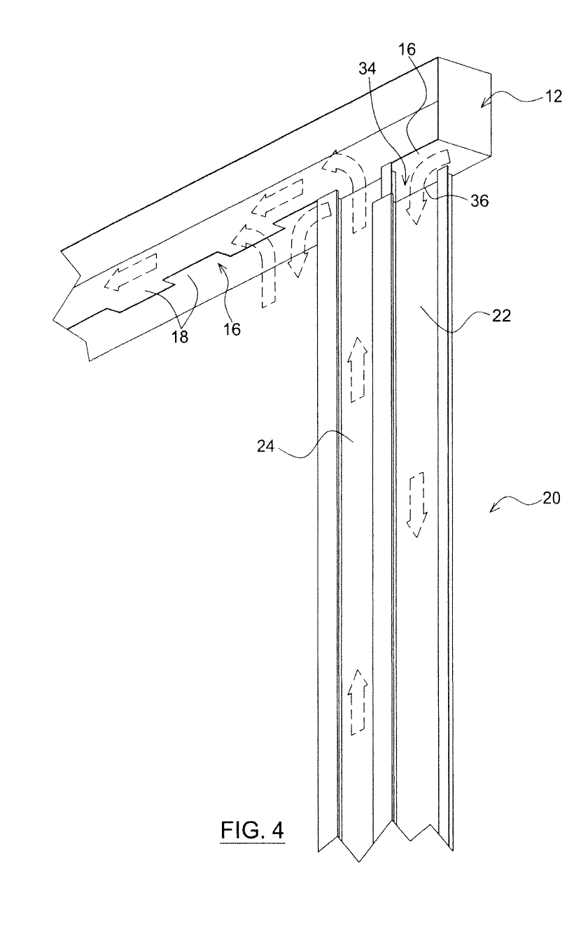

As best shown in FIG. 4, the receiving face 16 of the plenum 12 is provided with alternating openings and closures 18 to accommodate an outlet of each collector module 20. This crenellated pattern is preferably provided along the rear edge of the receiving face 16. The top end 40 of each intake channel 22 is aligned with a respective closure 18, thereby blocking outside air from entering the plenum 12 at that position. Similarly, the top end 46 of each return channel 24 is aligned with and joined to a respective opening 18, thereby allowing heated air to flow from the return channel into the plenum.

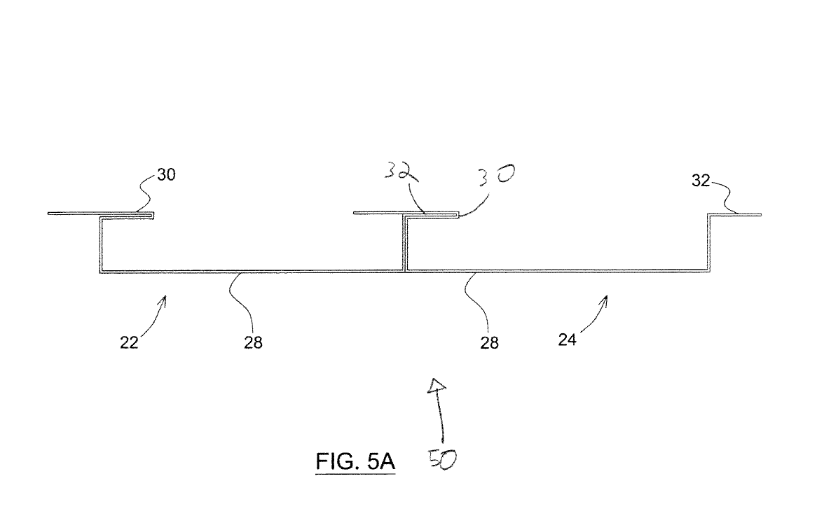

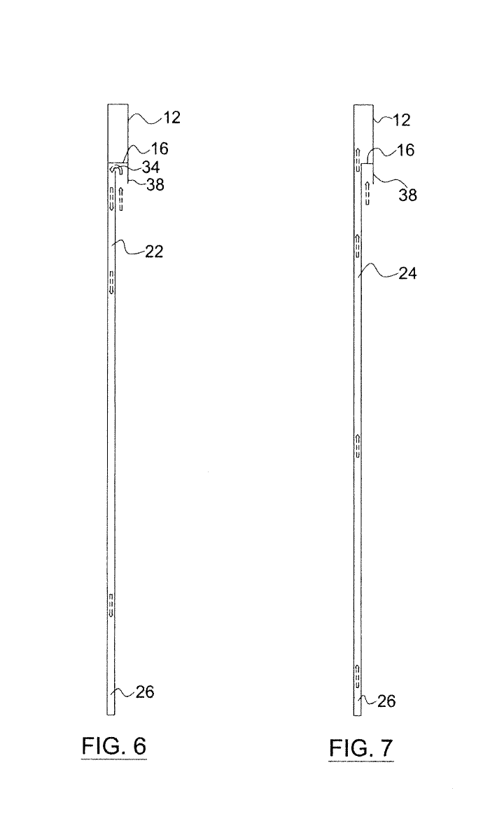

As shown in FIGS. 6 and 7, a hood 38 preferably extends from the bottom of the plenum 12, in front of the collector modules 20 for sheltering their respective air intake openings 34. The hood 38 extends longitudinally over the length of the plenum 12 and downwards in front of the collector modules 20 and is sized to the air flow required. The hood 38 can be provided with a photovoltaic array thereacross in order to provide additional use of the incident solar energy. It will be appreciated that in such an embodiment, it may be preferable to extend the photovoltaic hood either above the plenum 12 or farther downwards than what is illustrated.

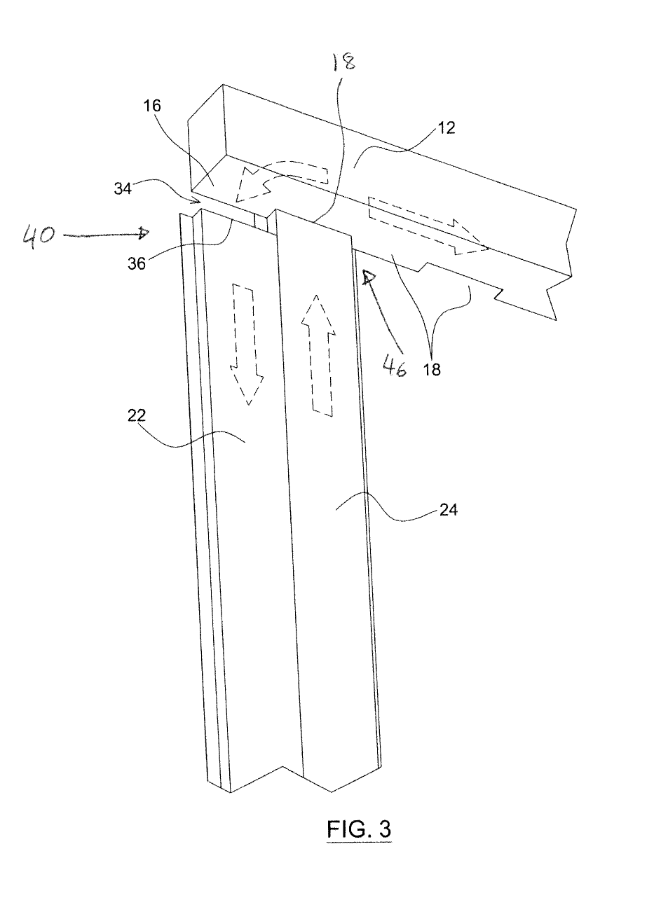

Referring to FIGS. 3 and 4, the top end 46 of the long channel 24 interconnects with the opening the plenum 12. This connects the module 20 to the plenum 12 and also directs the air heated after passing through the collector module 20 into the plenum 12 and towards the building. The building ventilation system 8 is connected to the plenum 12 builds up a negative pressure therein which thus acts as an aspiration plenum. Air circulating in the long channel 24 is dragged first into the plenum 12 and then into the building's ventilation system 8 where it can be used in a number of different ways.

The long channel 24 can be connected to the plenum 12 in different ways, such as with screws, soldering or simply by tightly fitting the long channel into a corresponding opening 18 of the plenum's receiving face 16. Preferably, caulking can be added at the interconnection of the long channel 24 with the plenum 12 to provide an insulated interconnection, less subject to leaks. In this preferred embodiment, the length of the short channel 22 of the collector module 20 is reduced in respect to the long channel 24 by a factor of channel depth, thus creating the air intake opening located between the top edge 36 of the short channel 22 and the receiving face 16 of the plenum 12.

As shown in FIG. 2, a connector 26, or closing element, closes the collector modules 20 at each of their bottom ends 42 and 44. The connector units 27 each connect a given short channel 22 with the corresponding long channel 24. The footer 26 and its units 27 are preferably made of a metallic or non-metallic material, and can take any size and shape, as long as they create a passage between the short 22 and the long 24 channels, ensuring air flow continuity between the two channels 22 and 24.

In use, and referring to FIGS. 1 to 5, fresh outside air enters the air intake 34 and circulates downward through the shorter channel 22. At the bottom end 42 of the channel 22, the air is redirected towards the long channel 24 by the connector unit 27. The air then circulates upward along the long channel 24 and is then aspired by the plenum 12 and onward into the building's ventilation system 8.

The exposed, outer surface of each channel 22 and 24 forms an absorber surface 50 which, as discussed above, is heated by sunlight and radiant energy. This heat energy is transmitted to the air travelling through the backpass collector 14 as it travels along its boustrophedonic route.

An advantage of the solar thermal system is its low cost versus performance. This new system provides a good value in terms of energy delivered vs. total installed costs. The system is also advantageously simple and easy to install. The system may be built onsite or constructed in modular units.

A solar thermal or ventilation system in accordance with the present invention can effectively optimize the length of the path and the speed of the fresh air within the collector, thereby improving the heat transfer from the solar collector to the air flow, while the modular sections of air channels in which the air circulates are each optimized for air flow and heat gain. Heat that is produced along the outside of the collector will tend to rise and be drawn under the hood and air intake opening, to circulate in the modules where its temperature is further increased.

Although the preferred embodiment described herein focused on the solar heating of air, it will be appreciated that a collector module, a backpass collector and/or a solar thermal system in accordance with the present invention could also, in some circumstances, be used provide cool air to a ventilation system or the like.

As will be appreciated, the present invention is an improvement and presents several advantages over other related devices known in the prior art.

Of course, numerous modifications could be made to the above-described embodiments without departing from the scope of the invention, as apparent to a person skilled in the art.

1-15. (canceled)

16. A solar thermal system for transporting air, the solar thermal system comprising:
a) backpass collector comprising a plurality of collector modules for transporting air in parallel, each collector module comprising:
i. an intake channel comprising opposite first and second ends;
ii. air intake formed at the first end of the intake channel;
iii. a return channel extending alongside the intake channel and comprising opposite first and second en ds, the first end of the return channel being proximate the second end of the intake channel;
iv. a connector unit connecting the second end of the intake channel to the first end of the return channel; and
v. an absorber surface formed by the intake and return channels for absorbing energy;
b) a plenum for receiving air in parallel from the second end of each return channel, the plenum comprising a receiving face which includes a plurality of alternating openings and closures, each opening being aligned with a respective return channel and each closure being aligned with a respective intake channel; and
wherein, for each of said collector modules, outside air is drawn into the intake channel via the air intake, is conveyed out of the intake channel and into the return channel by the connector, and passes from the return channel into the plenum.

17. The solar thermal system of claim 16, wherein the intake and return channels are oriented vertically and the plenum is oriented horizontally.

18. The solar thermal system of claim 17, wherein the plenum and connector unit are above and below the intake and return channels, respectively.

19. The solar thermal system of claim 16, wherein the intake and return channels are adjacent and parallel.

20. The solar thermal system of claim 16, wherein, for each of said collector modules, the intake channel is shorter in length than the return channel.

21. The solar thermal system of claim 20, wherein the air intake of each of said collector modules is formed between the first end of the corresponding intake channel and the plenum.

22. The solar thermal system of claim 16, wherein the intake and return channels of said collector modules are formed from bent channel plates.

23. The solar thermal system of claim 22, wherein, for each of said collector modules, the bent plate which forms the intake channel forms one of a female and male joint and the bent plate which forms the return channel forms the other of a female and male joint, the male joint fitting into the female joint for aligning the intake and return channels side-by-side.

24. The solar thermal system of claim 16, wherein, for each of said collector modules, at least one of the intake channel, the return channel and the footer unit are made of a metallic material.

25. The solar thermal system of claim 16, further comprising a hood extending from the plenum across each air intake.

26. The solar thermal system of claim 16, wherein the hood comprises a photovoltaic array extending thereacross.

27. The solar thermal system of claim 16, wherein the alternating openings and closures are formed along a rear edge of the receiving face in a crenellated pattern.
